(19) United States
(12) Patent Application Publication
(10) Pub. No.: US 2026/0150474 A1
(43) Pub. Date: May 28, 2026

(54) DISPLAY PANEL

(71) Applicant: AUO Corporation, Hsinchu City (TW)

(72) Inventors: Jui-Ping Yu, Hsinchu City (TW); Jia Hao Hsu, Hsinchu City (TW); Kun-Cheng Tien, Hsinchu City (TW)

(73) Assignee: AUO Corporation, Hsinchu City (TW)

(21) Appl. No.: 19/239,998

(22) Filed: Jun. 17, 2025

(30) Foreign Application Priority Data
Nov. 22, 2024 (TW) 113145040

(51) Int. Cl. H10H 29/856

(52) U.S. Cl. CPC H10H 29/856

(57) ABSTRACT

A display panel including a substrate, a light-emitting element, a reflective layer and a microlens is provided. The light-emitting element is disposed on the substrate and has a forward light-emitting surface facing away from the substrate and a lateral light-emitting surface connected to the forward light-emitting surface. The reflective layer is disposed on the substrate and covers the lateral light-emitting surface of the light-emitting element. The reflective layer has a flat surface facing away from the substrate. The forward light-emitting surface of the light-emitting element has a first height relative to a substrate surface of the substrate. The flat surface of the reflective layer has a second height relative to the substrate surface. The first height is greater than the second height. The microlens is disposed on the light-emitting element and covers the forward light-emitting surface.

### CROSS-REFERENCE TO RELATED APPLICATION

This application claims the priority benefit of Taiwan application serial no. 113145040, filed on Nov. 22, 2024. The entirety of the above-mentioned patent application is hereby incorporated by reference herein and made a part of this specification.

### BACKGROUND

### Technical Field

The disclosure relates to a display panel, and more particularly to a display panel provided with a light-emitting element and a microlens.

### Description of Related Art

In self-emissive display panels, in addition to light being emitted in the forward direction, the light-emitting element may also emit light laterally. To enhance the front-view luminance of the display panel, beyond improving the light emission efficiency of the light-emitting element itself, a concept has been proposed in which lateral light emitted by the light-emitting element is guided to be emitted through the forward light-emitting surface and a microlens is provided on the forward light-emitting surface. For example, by covering the lateral light-emitting surface of the light-emitting element with a reflective layer, the lateral light can be reflected and its probability of emission through the forward light-emitting surface can be increased. However, the process margin of the reflective layer is susceptible to reduction due to the positional shift of the light-emitting element bonded onto the substrate.

For instance, if the thickness of the reflective layer is too small, it may only partially cover the lateral light-emitting surface to meet the alignment requirements of subsequent layers (such as a light-shielding layer for enhancing color purity and contrast), but this would compromise part of the forward light-emission efficiency. Conversely, if the reflective layer is too thick to fully cover the lateral light-emitting surface of the light-emitting element, although the reuse rate of lateral light may be maximized, the optical performance of subsequent layers can easily degrade due to the positional shift of the light-emitting element. Therefore, how to balance the alignment requirements of subsequent layers and process margin in the presence of positional shift of the light-emitting element remains an urgent issue to be addressed.

### SUMMARY

The disclosure provides a display panel with improved alignment accuracy between the microlens and the light-emitting element.

A display panel of the disclosure includes a substrate, a light-emitting element, a reflective layer and a microlens. The light-emitting element is disposed on the substrate and has a forward light-emitting surface facing away from the substrate and a lateral light-emitting surface connected to the forward light-emitting surface. The reflective layer is disposed on the substrate and covers the lateral light-emitting surface of the light-emitting element. The reflective layer has a flat surface facing away from the substrate. The forward light-emitting surface of the light-emitting element has a first height relative to a substrate surface of the substrate. The flat surface of the reflective layer has a second height relative to the substrate surface. The first height is greater than the second height. The microlens is disposed on the light-emitting element and covers the forward light-emitting surface.

A display panel of the disclosure includes a substrate, a light-emitting element, a reflective layer and a microlens. The light-emitting element is disposed on the substrate and has a forward light-emitting surface facing away from the substrate and a lateral light-emitting surface connected to the forward light-emitting surface. The reflective layer is disposed on the substrate and has a flat surface facing away from the substrate and a protruding portion protruding from the flat surface. The protruding portion covers the lateral light-emitting surface. The microlens is disposed on the light-emitting element and covers the forward light-emitting surface. The microlens covers the protruding portion of the reflective layer.

Based on the above, in the display panel of one embodiment of the disclosure, the reflective layer exhibits a self-alignment characteristic with respect to the light-emitting element during processing, such that the flat surface of the reflective layer is closer to the substrate surface than the forward light-emitting surface of the light-emitting element. Accordingly, the impact of a positional shift of the light-emitting element during bonding to the substrate on the process margin of the reflective layer can be effectively avoided. Furthermore, covering the forward light-emitting surface of the light-emitting element with the microlens not only enhances the alignment accuracy between the microlens and the light-emitting element, but also significantly mitigates the impact of positional shift of the light-emitting element during bonding to the substrate on the processing of subsequent film structures.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic cross-sectional view of a display panel according to a first embodiment of the disclosure.

FIGS. 2A to 2C are schematic cross-sectional views illustrating a manufacturing process of the display panel of FIG. 1.

FIG. 3 is a schematic cross-sectional view of a display panel according to a second embodiment of the disclosure.

FIGS. 4A to 4D are schematic cross-sectional views illustrating a manufacturing process of the display panel of FIG. 3.

FIG. 5 is a schematic cross-sectional view of a display panel according to a third embodiment of the disclosure.

FIGS. 6A to 6E are schematic cross-sectional views illustrating a manufacturing process of the display panel of FIG. 5.

### DESCRIPTION OF THE EMBODIMENTS

As used herein, the terms “approximately,” “about,” “substantially,” or “essentially” include the stated values as well as average values within an acceptable deviation range as would be determined by a person skilled in the art, taking into account specific quantities of measurement and the errors associated with measurement (i.e., limitations of the measurement system). For example, “about” may refer to within one or more standard deviations from the stated value, or within ±30%, ±20%, ±15%, ±10%, or ±5%. Furthermore, depending on the nature of the measurement, cutting process, or other relevant properties, the terms “approximately,” “about,” “substantially,” or “essentially” may be interpreted with a selectively acceptable deviation range or standard deviation, and a single standard deviation does not necessarily apply to all properties.

In the drawings, for clarity, the thicknesses of layers, films, panels, and regions are exaggerated. It should be understood that when components such as layers, films, regions, or substrates are described as being “on” or “connected to” another component, they may be directly on or connected to the other component, or intermediate components may also be present. Conversely, when components are described as being “directly on” or “directly connected to” another component, no intermediate components are present. As used herein, “connected” may refer to physical and/or electrical connection. Additionally, “electrically connected” may still allow for other components to exist between the two elements.

Moreover, relative terms such as “lower” or “bottom” and “upper” or “top” may be used herein to describe the relationship between components as shown in the FIG.s. It should be understood that such relative terms are intended to encompass different orientations of the device beyond those shown in the drawings. For example, if a device in a drawing is flipped, the component described as being “below” another component may now be positioned “above” it. Thus, exemplary terms such as “lower” may include both “lower” and “upper” orientations, depending on the specific orientation in the FIG.s. Similarly, a component described as being “under” or “beneath” another may also be situated “over” or “above” it if the FIG. is flipped. Therefore, exemplary terms like “above” or “below” may include both orientations.

The exemplary embodiments described herein are referenced to schematic cross-sectional views, which are idealized examples. Variations in the illustrated shapes due to, for example, manufacturing techniques and/or tolerances are to be expected. Therefore, the embodiments described herein should not be construed as limited to the specific shapes illustrated, but rather include shape deviations that result from manufacturing. For instance, regions shown or described as flat may exhibit rough and/or nonlinear characteristics. Additionally, sharp corners shown in the drawings may in reality be rounded. As such, the regions illustrated in the FIG.s are essentially schematic and are not intended to depict exact shapes, nor to limit the scope of the claimed invention.

Detailed reference will now be made to exemplary embodiments of the present invention, examples of which are illustrated in the accompanying drawings. Wherever possible, the same reference numerals are used throughout the drawings and description to refer to the same or like parts.

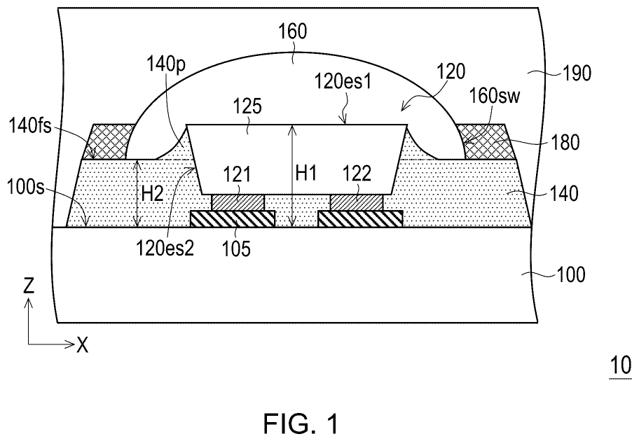

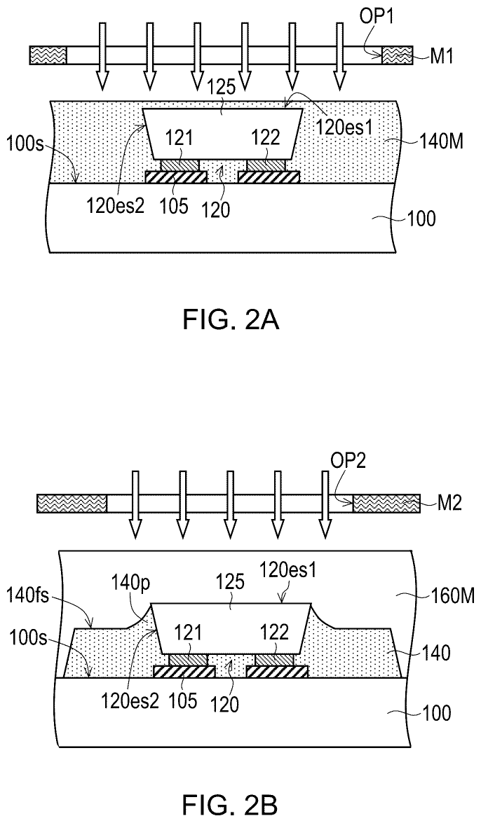

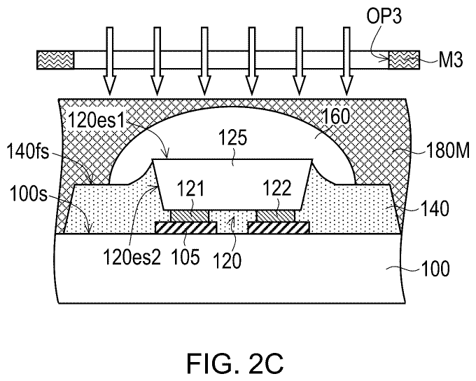

FIG. 1 is a schematic cross-sectional view of a display panel according to a first embodiment of the disclosure. FIGS. 2A to 2C are schematic cross-sectional views illustrating a manufacturing process of the display panel of FIG. 1. Referring to FIG. 1, a display panel 10 includes a substrate 100 and a light-emitting element 120. The light-emitting element 120 is disposed on the substrate 100. In the embodiment, the substrate 100, for example, is a circuit board provided with a pixel circuit layer (not shown) and a plurality of bonding pads 105. The light-emitting element 120 is adapted to be bonded to the bonding pads 105 to electrically connect the substrate 100. Although only one light-emitting element 120 is illustrated in FIG. 1, it is understood that the display panel 10 may include a plurality of light-emitting elements 120 arranged in an array on the substrate 100.

For example, the light-emitting element 120 may be a micro light-emitting diode (micro-LED) and includes a first electrode 121, a second electrode 122, and an epitaxial structure layer 125. The epitaxial structure layer 125 may include a first-type semiconductor layer (not shown), a second-type semiconductor layer (not shown), and a light-emitting layer (not shown), wherein the light-emitting layer is disposed between the first-type semiconductor layer and the second-type semiconductor layer. The first electrode 121 and the second electrode 122 are electrically connected to the first-type semiconductor layer and the second-type semiconductor layer, respectively. The first electrode 121 and the second electrode 122 of the light-emitting element 120 may be respectively bonded to two bonding pads 105 to achieve electrical connection between the light-emitting element 120 and the substrate 100.

In the embodiment, the first electrode 121 and the second electrode 122 of the light-emitting element 120 may be disposed on the same side of the epitaxial structure layer 125 facing the substrate 100. More specifically, the light-emitting element 120 may be a flip-chip type micro light-emitting diode. In the embodiment, the light-emitting element 120 has a forward light-emitting surface 120es1 facing away from the substrate 100 and a lateral light-emitting surface 120es2 connected to the forward light-emitting surface 120es1. The lateral light-emitting surface 120es2 may surround the forward light-emitting surface 120es1.

To enhance the emission intensity at the forward light-emitting surface 120es1 of the light-emitting element 120, the display panel 10 further includes a reflective layer 140 disposed on the substrate 100, and the reflective layer 140 covers the lateral light-emitting surface 120es2 of the light-emitting element 120. The reflective layer 140 is adapted to reflect the light emitted from the light-emitting layer (not shown) of the light-emitting element 120 toward the lateral light-emitting surface 120es2 back into the epitaxial structure layer 125, thereby increasing the probability of light exiting through the forward light-emitting surface 120es1.

In detail, the reflective layer 140 has a flat surface 140fs facing away from the substrate 100 and a protruding portion 140p protruding from the flat surface 140fs. Notably, the forward light-emitting surface 120es1 of the light-emitting element 120 has a height H1 relative to a substrate surface 100s of the substrate 100, while the flat surface 140fs has a height H2 relative to the substrate surface 100s, and the height H1 is greater than the height H2. In other words, the light-emitting element 120 protrudes from the flat surface 140fs of the reflective layer 140.

On the other hand, the protruding portion 140p of the reflective layer 140 is disposed surrounding the lateral light-emitting surface 120es2 of the light-emitting element 120 and covers a part of the lateral light-emitting surface 120es2 of the light-emitting element 120. More specifically, the protruding portion 140p covers the part of the lateral light-emitting surface 120es2 that is higher than the flat surface 140fs. For example, in the embodiment, the protruding portion 140p of the reflective layer 140 directly contacts and covers the part of the lateral light-emitting surface 120es2. That is, the protruding portion 140p may directly cover the part of the lateral light-emitting surface 120es2 of the light-emitting element 120. However, the disclosure is not limited thereto. In other embodiments, additional film layers may be disposed between the protruding portion 140p and the lateral light-emitting surface 120es2 of the light-emitting element 120.

To adjust the light distribution pattern of the light-emitting element 120, the display panel 10 further includes a microlens 160 disposed on the light-emitting element 120. Notably, the microlens 160 covers the forward light-emitting surface 120es1 of the light-emitting element 120 and the protruding portion 140p of the reflective layer 140. For example, in the embodiment, the microlens 160 is in direct contact with the forward light-emitting surface 120es1 of the light-emitting element 120 and the protruding portion 140p of the reflective layer 140. That is, the microlens 160 may directly cover the forward light-emitting surface 120es1 and the protruding portion 140p. However, the disclosure is not limited thereto. In other embodiments, additional film layers may be disposed between the microlens 160 and the light-emitting element 120 (and/or the protruding portion 140p), and the presence of these film layers does not affect the coverage relationship of the microlens 160 with respect to the light-emitting element 120.

To enhance display contrast, the display panel 10 may further include a light-shielding layer 180 disposed on the reflective layer 140. The light-shielding layer 180 covers the flat surface 140fs of the reflective layer 140 and a sidewall surface 160sw of the microlens 160 surrounding the forward light-emitting surface 120es1 and is configured to absorb undesired directional light and ambient light. The display panel 10 may further include an encapsulation layer 190 covering the microlens 160 and the light-shielding layer 180. For example, in the embodiment, the light-shielding layer 180 is in direct contact with the flat surface 140fs of the reflective layer 140 and the sidewall surface 160sw of the microlens 160 surrounding the forward light-emitting surface 120es1. That is, the light-shielding layer 180 may directly cover the flat surface 140fs of the reflective layer 140 and the sidewall surface 160sw of the microlens 160 surrounding the forward light-emitting surface 120es1. However, the disclosure is not limited thereto. In other embodiments, additional film layers may be disposed between the light-shielding layer 180 and the reflective layer 140 and/or the sidewall surface 160sw of the microlens 160.

The following provides an exemplary description of a manufacturing process of the display panel 10.

Referring to FIG. 2A, after the light-emitting element 120 is bonded to the bonding pads 105 of the substrate 100, forming a reflective material layer 140M on the substrate surface 100s to cover the light-emitting element 120. The material of the reflective material layer 140M may include white or highly reflective material. Then, a photomask M1 is used to perform an exposure and development process on the reflective material layer 140M. The photomask M1 has an opening OP1 overlapping the light-emitting element 120, and in any direction parallel to the substrate surface 100s, a width of the opening OP1 is greater than a width of the light-emitting element 120.

In the embodiment, the reflective material layer 140M may be, for example, a negative photoresist, but the disclosure is not limited thereto. After the exposure and development process, the reflective material layer 140M forms a reflective layer 140, as shown in FIG. 2B. It is specifically noted that the exposure process of the reflective material layer 140M may be performed with underexposure. Therefore, after the development process, a portion of the reflective material layer 140M above the forward light-emitting surface 120es1 of the light-emitting element 120 is removed, leaving only a portion covering the lateral light-emitting surface 120es2. Accordingly, a self-aligned configuration of the reflective layer 140 relative to the light-emitting element 120 is achieved. Even if there is an unexpected positional shift of the light-emitting element 120 during the bonding process with the substrate 100, it will not affect the alignment accuracy of the reflective layer 140.

Next, forming a microlens material layer 160M on the reflective layer 140, and a photomask M2 is used to perform an exposure and development process on the microlens material layer 160M. The photomask M2 has an opening OP2 overlapping the light-emitting element 120, and in any direction parallel to the substrate surface 100s, a width of the opening OP2 may be greater than or equal to the width of the light-emitting element 120. In the embodiment, the microlens material layer 160M is made of, for example, an organic negative photoresist, but the disclosure is not limited thereto. After the exposure and development process, the microlens material layer 160M forms a microlens 160, as shown in FIG. 2B and FIG. 2C. In the embodiment, the width of the opening OP2 of the photomask M2 is, for example, greater than the width of the light-emitting element 120. Therefore, the resulting microlens 160 also covers the protruding portion 140p of the reflective layer 140.

The exposure process of the microlens material layer 160M is, for example, performed with strong exposure. Therefore, after the development process, a portion of the microlens material layer 160M above the forward light-emitting surface 120es1 of the light-emitting element 120 is retained, while the unexposed or insufficiently exposed portions are removed. Notably, the profile of the microlens 160 can be adjusted by varying the exposure dose. Since the microlens 160 covers the forward light-emitting surface 120es1 of the light-emitting element 120, the alignment accuracy of the microlens 160 relative to the light-emitting element 120 can be significantly improved, thereby reducing the impact of positional shift of the light-emitting element 120 during bonding to the substrate 100 on the process of the subsequent layer structure.

Referring to FIG. 2C, next, forming a light-shielding material layer 180M on the reflective layer 140, and a photomask M3 is used to perform exposure and development on the light-shielding material layer 180M. The photomask M3 includes an opening OP3 overlapping the light-emitting element 120, and in any direction parallel to the substrate surface 100s, a width of the opening OP3 is greater than the width of the microlens 160. In the embodiment, the light-shielding material layer 180M is, for example, a negative photoresist, but the disclosure is not limited thereto. After the exposure and development process, the light-shielding material layer 180M forms a light-shielding layer 180 as shown in FIG. 1.

Specifically, the exposure process of the light-shielding material layer 180M is, for example, performed with underexposure. Therefore, after the development process, a portion of the light-shielding material layer 180M above the microlens 160 and overlapping the forward light-emitting surface 120es1 is removed, leaving only the portion covering the sidewall surface 160sw of the microlens 160. Accordingly, a self-aligned configuration of the light-shielding layer 180 relative to the microlens 160 is achieved. Even if there is an unexpected positional shift of the light-emitting element 120 during the bonding process with the substrate 100, it will not affect the alignment accuracy of the light-shielding layer 180.

Finally, forming an encapsulation layer 190 to cover the microlens 160 and the light-shielding layer 180. The material of the encapsulation layer 190 may include photoresist, resin, silicone, or other suitable materials. At this point, the fabrication of the display panel 10 shown in FIG. 1 is completed. The display panel 10 includes a substrate 100, a light-emitting element 120, a reflective layer 140, and a microlens 160. The reflective layer 140 is disposed on the substrate 100 and covers the lateral light-emitting surface 120es2 of the light-emitting element 120. Since the reflective layer 140 exhibits a self-alignment characteristic with respect to the light-emitting element 120 during processing, the flat surface 140fs of the reflective layer 140 is positioned closer to the substrate surface 100s than the forward light-emitting surface 120es1 of the light-emitting element 120. Accordingly, the impact of a positional shift of the light-emitting element 120 during bonding to the substrate 100 on the process margin of the reflective layer 140 can be effectively avoided. On the other hand, the microlens 160 is disposed on the light-emitting element 120 and covers the forward light-emitting surface 120es1. Accordingly, not only the alignment accuracy of the microlens 160 relative to the light-emitting element 120 can be effectively improved, but also the impact of a positional shift of the light-emitting element 120 during bonding to the substrate 100 on the process of the subsequent layer structure (e.g., the light-shielding layer 180) can be greatly reduced.

The following will enumerate additional embodiments to explain the present invention in detail. Identical components are denoted by the same reference numerals, and descriptions of identical technical content are omitted. For the omitted parts, please refer to the foregoing embodiment; redundant descriptions will not be repeated here.

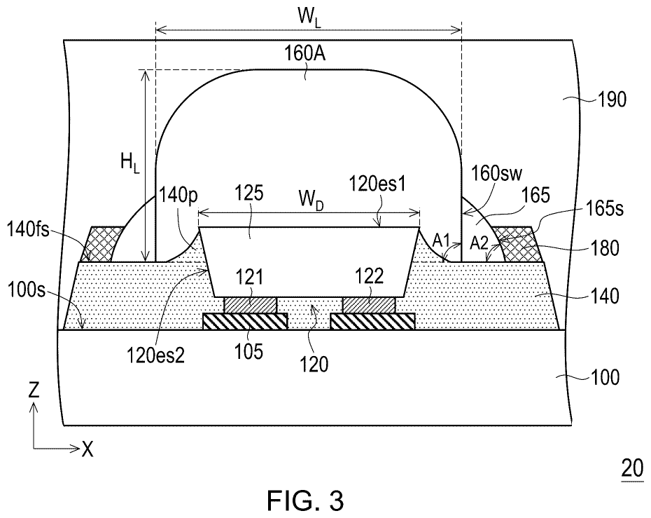

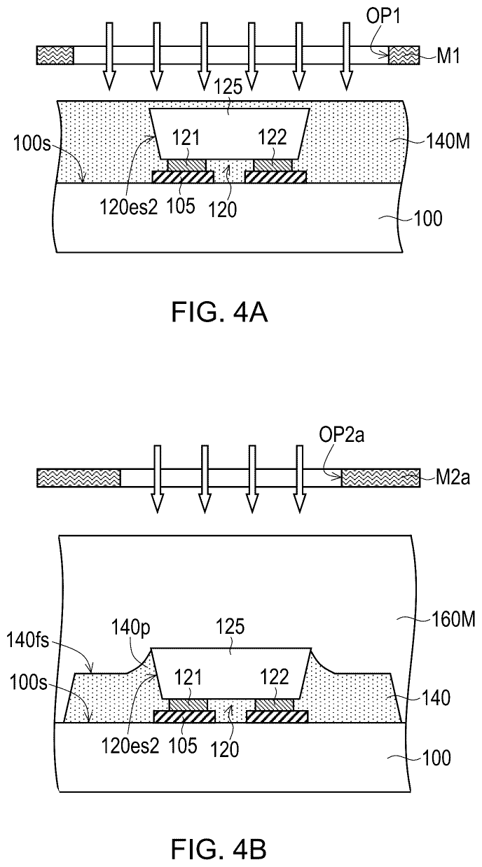

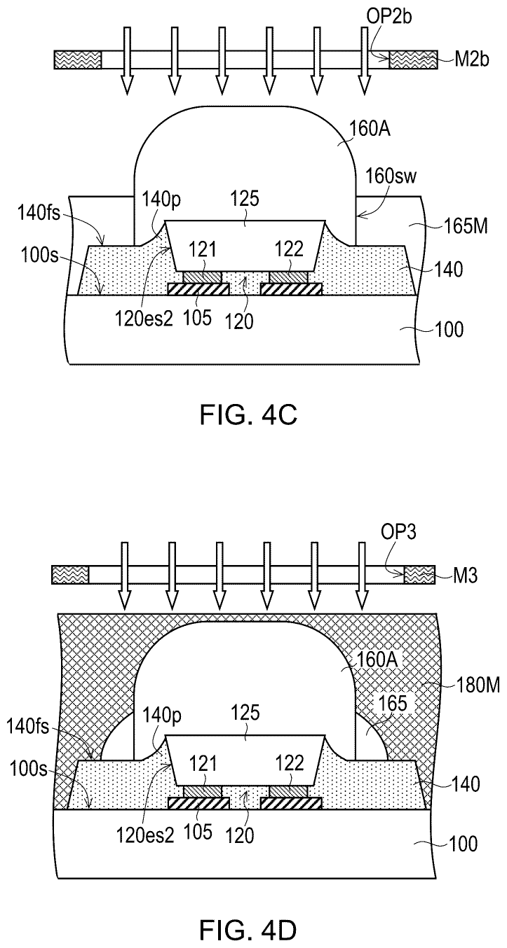

FIG. 3 is a schematic cross-sectional view of a display panel according to a second embodiment of the disclosure. FIGS. 4A to 4D are schematic cross-sectional views illustrating a manufacturing process of the display panel of FIG. 3. Referring to FIG. 3, the difference between a display panel 20 of the embodiment and the display panel 10 in FIG. 1 lies in the configuration of the microlens. Specifically, in the embodiment, the display panel 20 further includes a side-wing microlens 165 disposed on the reflective layer 140 and covering the sidewall surface 160sw of the microlens 160A. For example, in the embodiment, the side-wing microlens 165 is in direct contact with the sidewall surface 160sw of the microlens 160A. That is, the side-wing microlens 165 may directly cover the sidewall surface 160sw of the microlens 160A. However, the disclosure is not limited thereto. In other embodiments, additional film layers may be disposed between the side-wing microlens 165 and the sidewall surface 160sw of the microlens 160A.

In detail, the microlens 160A and the light-emitting element 120 respectively have a lens width W_{L} and an element width W_{D} in any direction (e.g., the X direction) parallel to the substrate surface 100s, and the microlens 160A has a lens height H_{L} in a normal direction (e.g., the Z direction) of the substrate surface 100s. In the embodiment, the microlens 160A may have a relatively large height-to-width ratio. Preferably, a ratio of the lens height H_{L} to the lens width W_{L} is greater than or equal to 0.2 and less than or equal to 1.0, and the ratio of the lens width WL to the element width W_{D} is greater than or equal to 1.0 and less than or equal to 1.5.

Compared with the microlens 160 in FIG. 1, the microlens 160A in the embodiment has a greater lens height, enabling its focal point to be closer to the forward light-emitting surface 120es1 of the light-emitting element 120, thereby further enhancing the optical performance of the microlens 160A, such as the forward light-emitting efficiency, but the disclosure is not limited thereto.

It is particularly noted that, in the embodiment, the side-wing microlens 165 does not overlap the forward light-emitting surface 120es1 of the light-emitting element 120 in a normal direction (e.g., the Z direction) of the substrate surface 100s. Through the provision of the side-wing microlens 165, the flexibility in adjusting the light distribution pattern of the light-emitting element 120 can be further enhanced.

In the embodiment, since the sidewall surface 160sw of the microlens 160A is covered with the side-wing microlens 165, the light-shielding layer 180 disposed on the reflective layer 140 covers a side-wing surface 165s of the side-wing microlens 165. Preferably, a first angle A1 is included between the sidewall surface 160sw of the microlens 160A and the flat surface 140fs, and a second angle A2 is included between the side-wing surface 165s of the side-wing microlens 165 and the flat surface 140fs, wherein the second angle A2 is smaller than the first angle A1. For example, in the embodiment, the light-shielding layer 180 is in direct contact with the side-wing surface 165s of the side-wing microlens 165. That is, the light-shielding layer 180 may directly cover the side-wing surface 165s of the side-wing microlens 165. However, the disclosure is not limited thereto. In other embodiments, additional film layers may be provided between the light-shielding layer 180 and the side-wing surface 165s of the side-wing microlens 165.

The following provides an exemplary description of a manufacturing process of the display panel 20.

Referring to FIG. 4A, after the light-emitting element 120 is bonded to the bonding pads 105 on the substrate 100, forming a reflective material layer 140M on the substrate surface 100s to cover the light-emitting element 120. The material of the reflective material layer 140M may include white or highly reflective material. Then, a photomask M1 is used to perform an exposure and development process on the reflective material layer 140M. The photomask M1 includes an opening OP1 overlapping the light-emitting element 120, and in any direction parallel to the substrate surface 100s, a width of the opening OP1 is greater than a width of the light-emitting element 120.

In the embodiment, the reflective material layer 140M is, for example, a negative photoresist, but the disclosure is not limited thereto. After the exposure and development process, the reflective material layer 140M forms a reflective layer 140, as shown in FIG. 4B. It is specifically noted that the exposure process of the reflective material layer 140M is, for example, performed with under exposure. Therefore, after the development process, a portion of the reflective material layer 140M above the forward light-emitting surface 120es1 of the light-emitting element 120 is removed, leaving only a portion covering the lateral light-emitting surface 120es2. Accordingly, a self-aligned configuration of the reflective layer 140 relative to the light-emitting element 120 is achieved. Even if there is an unexpected positional shift of the light-emitting element 120 during the bonding process with the substrate 100, it will not affect the alignment accuracy of the reflective layer 140.

Next, forming a microlens material layer 160M on the reflective layer 140, and a photomask M2a is used to perform an exposure and development process on the microlens material layer 160M. The photomask M2a has an opening OP2a overlapping the light-emitting element 120, and in any direction parallel to the substrate surface 100s, a width of the opening OP2a may be greater than or equal to the width of the light-emitting element 120. In the embodiment, the microlens material layer 160M is made of an organic negative photoresist, but the disclosure is not limited thereto. After the exposure and development process, the microlens material layer 160M forms a microlens 160A, as shown in FIG. 4C. In the embodiment, the width of the opening OP2a of the photomask M2a is, for example, greater than the width of the light-emitting element 120. Therefore, the resulting microlens 160A also covers the protruding portion 140p of the reflective layer 140.

The exposure process of the microlens material layer 160M is, for example, performed with strong exposure. Therefore, after the development process, a portion of the microlens material layer 160M above the forward light-emitting surface 120es1 of the light-emitting element 120 is retained, while the unexposed or insufficiently exposed portions are removed. Notably, the profile of the microlens 160A can be adjusted by varying the exposure dose. Since the microlens 160A covers the forward light-emitting surface 120es1 of the light-emitting element 120, the alignment accuracy of the microlens 160A relative to the light-emitting element 120 can be significantly improved, thereby reducing the impact of positional shift of the light-emitting element 120 during bonding to the substrate 100 on the process of the subsequent layer structure.

Referring to FIG. 4C, next, forming a side-wing microlens material layer 165M on the reflective layer 140, and a photomask M2b is used to perform an exposure and development process on the side-wing microlens material layer 165M. The photomask M2b has an opening OP2b overlapping the light-emitting element 120 and the microlens 160A, and in any direction parallel to the substrate surface 100s, a width of the opening OP2b is greater than the width of the opening OP2a of the photomask M2a shown in FIG. 4B. In the embodiment, the side-wing microlens material layer 165M is, for example, made of an organic negative photoresist, but the disclosure is not limited thereto. After the exposure and development process, the side-wing microlens material layer 165M forms a side-wing microlens 165, as shown in FIG. 4D.

The exposure process of the side-wing microlens material layer 165M is, for example, performed with strong exposure. Therefore, after the development process, the unexposed or insufficiently exposed portions of the microlens material layer 160M are removed. Notably, the profile of the side-wing microlens 165 can be adjusted by varying the exposure dose. Preferably, the side-wing microlens 165 and the microlens 160A may have the same refractive index, and the choice of materials may optionally be the same or different.

Referring to FIG. 4D, next, forming a light-shielding material layer 180M on the reflective layer 140, and a photomask M3 is used to perform an exposure and development process on the light-shielding material layer 180M. The photomask M3 includes an opening OP3 overlapping the light-emitting element 120, and in any direction parallel to the substrate surface 100s, a width of the opening OP3 is greater than a width of the microlens 160A and the side-wing microlens 165. In the embodiment, the light-shielding material layer 180M is, for example, a negative photoresist, but the disclosure is not limited thereto. After the exposure and development process, the light-shielding material layer 180M forms a light-shielding layer 180, as shown in FIG. 3.

Specifically, the exposure process of the light-shielding material layer 180M is, for example, performed with underexposure. Therefore, after the development process, a portion of the light-shielding material layer 180M above the microlens 160A and the side-wing microlens 165 is removed, leaving only the portion covering the side-wing surface 165s of the side-wing microlens 165. Accordingly, a self-aligned configuration of the light-shielding layer 180 relative to the microlens 160A and the side-wing microlens 165 is achieved. Even if there is an unexpected positional shift of the light-emitting element 120 during the bonding process with the substrate 100, it will not affect the alignment accuracy of the light-shielding layer 180.

Finally, forming an encapsulation layer 190 to cover the microlens 160A, the side-wing microlens 165, and the light-shielding layer 180. The material of the encapsulation layer 190 may include photoresist, resin, silicone, or other suitable materials. At this point, the fabrication of the display panel 20 shown in FIG. 3 is completed. In the embodiment, by increasing the lens height H_{L} of the microlens 160A, the forward light-emitting efficiency of the display panel 20 can be effectively enhanced. Furthermore, the configuration of the side-wing microlens 165 can enhance the flexibility in adjusting light distribution pattern.

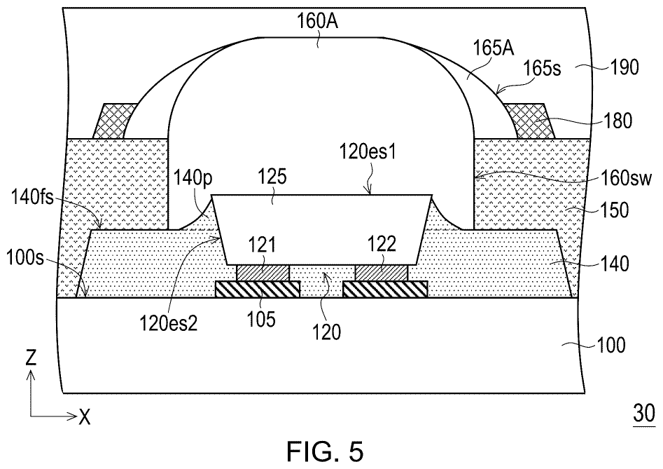

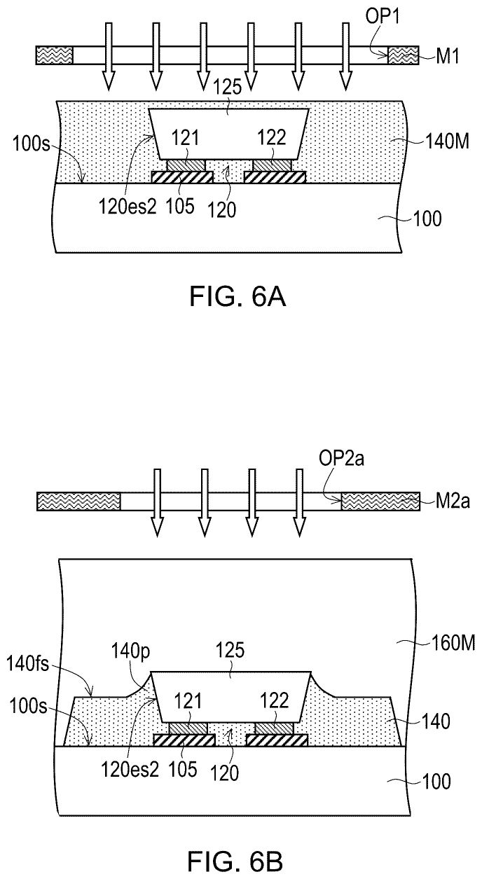

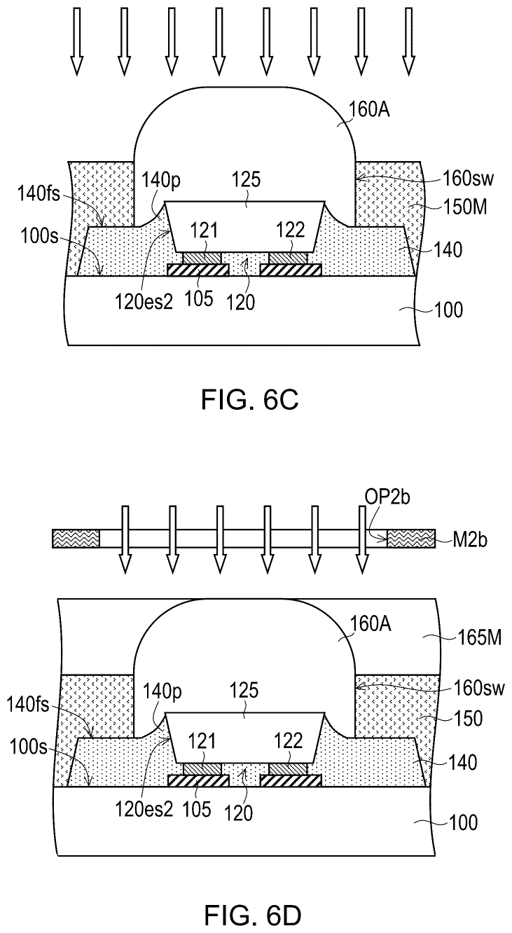

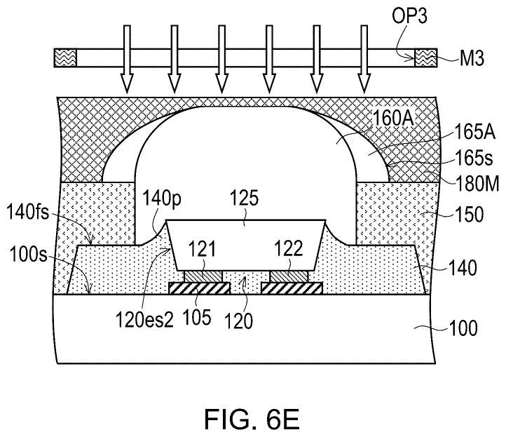

FIG. 5 is a schematic cross-sectional view of a display panel according to a third embodiment of the disclosure. FIGS. 6A to 6E are schematic cross-sectional views illustrating a manufacturing process of the display panel of FIG. 5. Referring to FIG. 5, the main difference between a display panel 30 of the embodiment and the display panel 20 of FIG. 3 lies in the configuration of the side-wing microlens. Specifically, in the embodiment, the display panel 30 may further include a planarization layer 150 disposed on the reflective layer 140 and covering a portion of the sidewall surface 160sw of the microlens 160A close to the reflective layer 140. For example, in the embodiment, the planarization layer 150 is in direct contact with a portion of the sidewall surface 160sw of the microlens 160A. That is, the planarization layer 150 may directly cover the portion of the sidewall surface 160sw of the microlens 160A. However, the disclosure is not limited thereto. In other embodiments, additional film layers may be disposed between the planarization layer 150 and the portion of the sidewall surface 160sw of the microlens 160A.

In the embodiment, a side-wing microlens 165A may be disposed on the planarization layer 150. Therefore, unlike the side-wing microlens 165 of FIG. 3 which covers a portion of the sidewall surface 160sw of the microlens 160A close to the reflective layer 140, the side-wing microlens 165A of the embodiment covers a portion of the sidewall surface 160sw of the microlens 160A that is farther from the reflective layer 140. In other words, the side-wing microlens 165A of the embodiment is disposed at a height relative to the microlens 160A is higher than that of the side-wing microlens 165 of FIG. 3, thereby further enhancing the forward light-emitting efficiency of the display panel 30.

The following provides an exemplary description of a manufacturing process of the display panel 30.

Referring to FIG. 6A, after the light-emitting element 120 is bonded to the bonding pads 105 on the substrate 100, forming a reflective material layer 140M on the substrate surface 100s to cover the light-emitting element 120. The material of the reflective material layer 140M may include white or highly reflective material. Then, a photomask M1 is used to perform an exposure and development process on the reflective material layer 140M. The photomask M1 has an opening OP1 overlapping the light-emitting element 120, and in any direction parallel to the substrate surface 100s, a width of the opening OP1 is greater than a width of the light-emitting element 120.

In the embodiment, the reflective material layer 140M is, for example, a negative photoresist, but the disclosure is not limited thereto. After the exposure and development process, the reflective material layer 140M forms a reflective layer 140, as shown in FIG. 6B. Notably, the exposure process of the reflective material layer 140M may be performed with underexposure. Therefore, after the development process, a portion of the reflective material layer 140M above the forward light-emitting surface 120es1 of the light-emitting element 120 is removed, leaving only portion covering the lateral light-emitting surface 120es2. Accordingly, a self-aligned configuration of the reflective layer 140 relative to the light-emitting element 120 is achieved. Even if there is an unexpected positional shift of the light-emitting element 120 during the bonding process with the substrate 100, it will not affect the alignment accuracy of the reflective layer 140.

Next, forming a microlens material layer 160M on the reflective layer 140, and a photomask M2a is used to perform an exposure and development process on the microlens material layer 160M. The photomask M2a has an opening OP2a overlapping the light-emitting element 120, and in any direction parallel to the substrate surface 100s, a width of the opening OP2a may be greater than or equal to the width of the light-emitting element 120. In the embodiment, the microlens material layer 160M is made of, for example, an organic negative photoresist, but the disclosure is not limited thereto. After the exposure and development process, the microlens material layer 160M forms a microlens 160A, as shown in FIG. 6C. In the embodiment, the width of the opening OP2a of the photomask M2a is greater than the width of the light-emitting element 120. Therefore, the resulting microlens 160A also covers the protruding portion 140p of the reflective layer 140.

The exposure process of the microlens material layer 160M may be performed with strong exposure. Therefore, after the development process, a portion of the microlens material layer 160M above the forward light-emitting surface 120es1 of the light-emitting element 120 is retained, while the unexposed or insufficiently exposed portions are removed. Notably, the profile of the microlens 160A can be adjusted by varying exposure dose. Since the microlens 160A covers the forward light-emitting surface 120es1 of the light-emitting element 120, the alignment accuracy of the microlens 160A relative to the light-emitting element 120 can be significantly improved, thereby reducing the impact of positional shift of the light-emitting element 120 during bonding to the substrate 100 on the process of the subsequent layer structure.

Referring to FIG. 6C and FIG. 6D, next, forming a planarization material layer 150M on the reflective layer 140, and performing an exposure process on the planarization material layer 150M to form a planarization layer 150. The material of the planarization layer 150 includes, for example, inorganic materials (e.g., silicon oxide, silicon nitride, or silicon oxynitride, but the disclosure is not limited thereto), organic materials (e.g., polyimide resin, epoxy resin, or acrylic resin, but the disclosure is not limited thereto), or other suitable materials.

Next, forming a side-wing microlens material layer 165M on the planarization layer 150, and a photomask M2b is used to perform an exposure and development process on the side-wing microlens material layer 165M. The photomask M2b has an opening OP2b overlapping the light-emitting element 120 and the microlens 160A, and in any direction parallel to the substrate surface 100s, a width of the opening OP2b is greater than the width of the opening OP2a of the photomask M2a shown in FIG. 6B. In the embodiment, the side-wing microlens material layer 165M is made of, for example, an organic negative photoresist, but the disclosure is not limited thereto. After the exposure and development process, the side-wing microlens material layer 165M forms a side-wing microlens 165, as shown in FIG. 6E.

The exposure process of the side-wing microlens material layer 165M may be, for example, performed with strong exposure. Therefore, after the development process, the unexposed or insufficiently exposed portions of the microlens material layer 160M are removed. Notably, the profile of the side-wing microlens 165 can be adjusted by varying exposure dose. In another modified embodiment (not shown), the microlens material layer may further include a portion located above the microlens 160A, which remains above the microlens 160A after the exposure and development process. In other word, the surface contour adjustment of the microlens 160A overlapping the forward light-emitting surface 120es1 may be simultaneously performed during the exposure and development process of the side-wing microlens.

Referring to FIG. 6E, after the fabrication of the side-wing microlens 165A is completed, forming a light-shielding material layer 180M on the planarization layer 150, and a photomask M3 is used to perform an exposure and development process on the light-shielding material layer 180M. The photomask M3 has an opening OP3 overlapping the light-emitting element 120, and in any direction parallel to the substrate surface 100s, a width of the opening OP3 is greater than a width of the microlens 160A and the side-wing microlens 165. In the embodiment, the light-shielding material layer 180M is, for example, a negative photoresist, but the disclosure is not limited thereto. After the exposure and development process, the light-shielding material layer 180M forms a light-shielding layer 180, as shown in FIG. 5.

It is particularly noted that the exposure process of the light-shielding material layer 180M may be performed with underexposure. Therefore, after the development process, a portion of the light-shielding material layer 180M above the microlens 160A and the side-wing microlens 165 is removed, leaving only the portion covering the side surface 165s of the side-wing microlens 165. Accordingly, a self-aligned configuration of the light-shielding layer 180 relative to the microlens 160A and the side-wing microlens 165A is achieved. Even if there is an unexpected positional shift of the light-emitting element 120 during the bonding process with the substrate 100, it will not affect the alignment accuracy of the light-shielding layer 180.

Finally, forming an encapsulation layer 190 to cover the microlens 160A, the side-wing microlens 165A, and the light-shielding layer 180. The material of the encapsulation layer 190 may include photoresist, resin, silicone, or other suitable materials. At this point, the fabrication of the display panel 30 shown in FIG. 5 is completed. In the embodiment, by increasing the height of the side-wing microlens 165A relative to the microlens 160A, the forward light-emitting efficiency of the display panel 30 can be further improved.

To sum up, in the display panel of one embodiment of the disclosure, the reflective layer exhibits a self-alignment characteristic with respect to the light-emitting element during processing, such that the flat surface of the reflective layer is closer to the substrate surface than the forward light-emitting surface of the light-emitting element. Accordingly, the impact of a positional shift of the light-emitting element during bonding to the substrate on the process margin of the reflective layer can be effectively avoided. Furthermore, covering the forward light-emitting surface of the light-emitting element with the microlens not only enhances the alignment accuracy between the microlens and the light-emitting element, but also significantly mitigates the impact of positional shift of the light-emitting element during bonding to the substrate on the processing of subsequent film structures.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A display panel, comprising:
a substrate;
a light-emitting element, disposed on the substrate and having a forward light-emitting surface facing away from the substrate and a lateral light-emitting surface connected to the forward light-emitting surface;
a reflective layer, disposed on the substrate and covering the lateral light-emitting surface of the light-emitting element, wherein the reflective layer has a flat surface facing away from the substrate, the forward light-emitting surface of the light-emitting element has a first height relative to a substrate surface of the substrate, the flat surface of the reflective layer has a second height relative to the substrate surface, and the first height is greater than the second height; and
a microlens, disposed on the light-emitting element and covering the forward light-emitting surface.

2. The display panel according to claim 1, wherein the reflective layer further has a protruding portion protruding from the flat surface and covering the lateral light-emitting surface, and the microlens covers the protruding portion of the reflective layer.

3. The display panel according to claim 1, wherein the microlens has a lens width along a direction parallel to the substrate surface and a lens height along a normal direction of the substrate surface, and a ratio of the lens height to the lens width is greater than or equal to 0.2 and less than or equal to 1.0.

4. The display panel according to claim 3, wherein the light-emitting element has an element width along the direction, and a ratio of the lens width to the element width is greater than or equal to 1.0 and less than or equal to 1.5.

5. The display panel according to claim 1, further comprising:
a side-wing microlens, disposed on the reflective layer, wherein the microlens has a sidewall surface surrounding the forward light-emitting surface, and the side-wing microlens covers the sidewall surface of the microlens.

6. The display panel according to claim 5, wherein the side-wing microlens covers the reflective layer and does not overlap the forward light-emitting surface of the light-emitting element in a normal direction of the substrate surface.

7. The display panel according to claim 5, wherein a first angle is included between the sidewall surface of the microlens and the flat surface, a second angle is included between the flat surface and a side-wing surface of the side-wing microlens connecting the reflective layer, and the second angle is smaller than the first angle.

8. The display panel according to claim 5, further comprising:
a light-shielding layer, disposed on the reflective layer and covering the reflective layer and a side-wing surface of the side-wing microlens connecting the reflective layer.

9. The display panel according to claim 1, further comprising:
a planarization layer, disposed on the reflective layer, wherein the microlens has a sidewall surface surrounding the forward light-emitting surface, and the planarization layer covers the sidewall surface of the microlens.

10. The display panel according to claim 9, further comprising:
a side-wing microlens, disposed on the planarization layer and covering the sidewall surface of the microlens.

11. The display panel according to claim 10, further comprising:
a light-shielding layer, disposed on the planarization layer and covering the planarization layer and a side-wing surface of the side-wing microlens connecting the reflective layer.

12. A display panel, comprising:
a substrate;
a light-emitting element, disposed on the substrate and having a forward light-emitting surface facing away from the substrate and a lateral light-emitting surface connected to the forward light-emitting surface;
a reflective layer, disposed on the substrate and having a flat surface facing away from the substrate and a protruding portion protruding from the flat surface, wherein the protruding portion covers the lateral light-emitting surface; and
a microlens, disposed on the light-emitting element and covering the forward light-emitting surface, wherein the microlens covers the protruding portion of the reflective layer.

13. The display panel according to claim 12, wherein the forward light-emitting surface of the light-emitting element has a first height relative to a substrate surface of the substrate, the flat surface of the reflective layer has a second height relative to the substrate surface, and the first height is greater than the second height.

14. The display panel according to claim 12, wherein the microlens has a lens width along a direction parallel to a substrate surface of the substrate and a lens height along a normal direction of the substrate surface, and a ratio of the lens height to the lens width is greater than or equal to 0.2 and less than or equal to 1.0.

15. The display panel according to claim 14, wherein the light-emitting element has an element width along the direction, and a ratio of the lens width to the element width is greater than or equal to 1.0 and less than or equal to 1.5.

16. The display panel according to claim 12, further comprising:
a side-wing microlens, disposed on the reflective layer, wherein the microlens has a sidewall surface surrounding the forward light-emitting surface, and the side-wing microlens covers the sidewall surface of the microlens.

17. The display panel according to claim 16, wherein the side-wing microlens covers the reflective layer and does not overlap the forward light-emitting surface of the light-emitting element along a normal direction of a substrate surface of the substrate.

18. The display panel according to claim 16, wherein a first angle is included between the sidewall surface of the microlens and the flat surface, a second angle is included between the flat surface and a side-wing surface of the side-wing microlens connecting the reflective layer, and the second angle is smaller than the first angle.

19. The display panel according to claim 12, further comprising:
a planarization layer, disposed on the reflective layer, wherein the microlens has a sidewall surface surrounding the forward light-emitting surface, and the planarization layer covers the sidewall surface of the microlens.

20. The display panel according to claim 19, further comprising:
a side-wing microlens, disposed on the planarization layer and covering the sidewall surface of the microlens.
